(19) United States
(12) Patent Application Publication
(10) Pub. No.: US 2026/0302715 A1
(43) Pub. Date: Oct. 1, 2026

(54) MODULATION TRANSFER SPECTROSCOPY DEVICE

(71) Applicant: THE SECRETARY OF STATE FOR DEFENCE, Salisbury, Wiltshire (GB)

(72) Inventor: Matthew David Himsworth, Salisbury, Wiltshire (GB)

(21) Appl. No.: 19/477,173

(22) PCT Filed: Apr. 16, 2024
(86) PCT No.: PCT/IB2024/053705

§ 371 Date: Oct. 21, 2025

(30) Foreign Application Priority Data
Apr. 21, 2023 (GB) 2305870.4

(51) Int. Cl. H01S 3/13; H01S 3/094

(52) U.S. Cl. CPC H01S 3/1303; H01S 3/094; H01S 3/1305

(57) ABSTRACT

A Modulation Transfer Spectroscopy (MTS) device comprising a vapour cell, a retroreflective optical modulation detector arranged to generate a pump laser beam from the probe laser beam emerging from the vapour cell, a modulation detector arranged to detect modulation in a probe laser beam, and a comparator arranged to provide a signal based on the phase of the modulation in the probe laser beam which can be used to stabilise the frequency of a laser. This provides for a more compact and robust MTS device.

The present invention relates to the field of Modulation Transfer Spectroscopy devices for laser frequency stabilisation, for use in quantum technology systems.

Many quantum technology systems use highly stabilized lasers. If left uncontrolled a laser will naturally drift in wavelength and the spectral purity of the emission itself may not be narrow enough for applications such as laser cooling and atomic clocks. To control the laser wavelength it must be ‘locked’ to a more stable reference, such as an absorption line in an atomic vapour. The absorption line acts like a wavelength-to-voltage converter that can be used to generate an electrical ‘error signal’ which is used as ‘feed-back’to the laser driver to stabilise the wavelength.

Atomic absorption peaks can be very broad due to Doppler shift from the motion of the gaseous atoms. Advanced spectroscopy techniques can be used to narrow the peak, typically called ‘Doppler-free spectroscopy’ (or Pump-probe spectroscopy, or saturation spectroscopy). This involves two counter-propagating laser beams generated from a single laser. A (typically intense) ‘pump’ beam causes the atomic transition to saturate which prevents it from absorbing more light. A (typically weak) ‘probe’ measures this change in absorption. The Doppler-shift of an atom's wavelength is dependent on its relative motion to the direction of the laser beam. As the beams are counter-propagating, they can only be ‘in resonance’ with atoms that are travelling perpendicularly to both beams, and therefore have less, or no, Doppler shift or broadening. The resulting dips in absorption can be up to ten times narrower and produce a much finer and sensitive error signal. The narrower the error signal, the better the laser stabilization.

The shape of the ‘error signal’ with respect to wavelength is important. It would ideally result in an electrical voltage which is zero at the resonance frequency and has opposite polarity either side of resonance, so that the correct signal can be sent to the laser to move it back onto resonance, however this shape is an ideal rather than typical outcome. The modulation slightly dithers the wavelength either side of an absorption peak and the gradient of the peak can be determined by RF homodyne demodulation techniques, similar to an FM radio.

One method of modulating a laser beam is called ‘Modulation Transfer Spectroscopy’ (MTS). Instead of modulating all of the laser beams used in the spectroscopy system, only the pump beam is modulated. As this beam is typically quite intense, the modulation causes a fluctuation in the refractive index of an atomic vapour in a vapour cell. The phase of an unmodulated and (typically) much weaker probe beam is altered accordingly and modulation sidebands are generated on it which are then detected with a Homodyne receiver. The physics is known as ‘4-wave mixing’ and depends on the X³ susceptibility of the atomic response to optical radiation. This technique reduces the number of absorption peaks, typically to one absorption peak, which makes finding and locking the laser easier. It is also is less susceptible to background noise sources such as temperature, intensity fluctuations and magnetic fields compared to other methods of modulating a laser beam.

One prior art publication which describes such an approach is “Compact modulation transfer spectroscopy module for highly stable laser frequency” by Sanglok et al in Optics and Laser in Engineering 146(2021 ).

To generate the modulation on the pump laser beam one conventional approach is to use an Acousto-Optical-Modulator (AOM) coupled with a lens and mirror-The AOM contains a medium that when actuated with an RF frequency causes a moving grating which deflects the laser beam (and the laser beam passes via a lens to a mirror and back through the same lens and back through the same AOM so as to have an adjusted frequency). By oscillating the RF frequency into the AOM medium, this oscillates the frequency of the laser. Another known approach is to use an Electro Optical Modulator (EOM).

Such devices involve splitting the input laser light into two paths, one of which is guided into the vapour chamber, whilst the other is guided around to the far side of vapour chamber to enter at the other end thereof. This requires precise alignment of relevant mirrors (and if an AOM is used this also requires careful alignment of the lens and mirror), which has been found to introduce sensitivity to environmental disturbances, and which thus limits the range of types of environment that the system will work reliably in.

The optical detector can most simply be a photodiode, which although sensitive to intensity, will output a periodically varying electrical signal (since the modulating optical frequency involves a modulating phase, meaning that the intensity also varies periodically). Typically this output will need to be amplified prior to being compared to the signal used to generate modulations in the pump laser beam. A suitable comparator, e.g. a frequency mixer, is selected to ensure that if the laser frequency has drifted downwards with respect to the relevant vapour absorption line being used, the comparator will output one voltage (E.g. a raised voltage) and if the laser frequency has drifted above that absorption line then the comparator will output an opposite voltage (E.g. a negative voltage)-any variation of this can be used provided that the resulting output signal can be used to adjust (and correct) the frequency of the laser. Configuration options to achieve this are known in the art (for example as described by Sanglok et al), but the simplest approach is to frequency mix the signal driving the optical modulator with the signal from the optical detector.

The conventional approach—as for example described by Sanglok et al (see FIG. 1 and the dashed rectangle in FIG. 2)—is to split the light from the laser into two beams; the stronger pump beam, and weaker probe beam. These are sent via two different paths to the two inlets of the vapour cell (in this case a rubidium vapour cell). The very recent article by Sanglok et al recent states the “we report a small lightweight and compact” MTS setup which “despite its small size . . . is best performance for MTB with Rb to our knowledge . . . ”. It is clearly therefore desirable to make an MTS system compact.

It has historically been assumed that the pump beam should be stronger than the probe beam. The inventor has understood that it is entirely feasible to use a pump beam that is weaker than the probe beam, since the maths of 4-wave-mixing does not rule this approach out—something that is not very widely understood. The inventor then proceeded to realise that, with this in mind, the optical layout can be simplified such as to eliminate any need to split the beam into two paths prior to entering the vapour cell. Instead, the beam enters one side of the vapour cell, and is reflected back with added modulation to provide the pump beam. This optical layout is dramatically simpler and thus can be manufactured as a smaller and more physically robust device.

The optical modulator is preferably an electro optical modulator arranged in front of a mirror, but can alternatively involve a piezo actuated mirror or other solutions such as acousto-optical modulators etc. A beam splitter (i.e. a partially reflective device) can be used to direct a portion of the light to be modulated and returned as the pump beam, with another portion being directed to the optical detector e.g. photodiode, however other methods of dividing the light beam into two portions can be used, conceivably even an in-line approach of arranging the retroreflective optical modulator and the optical detector side by side such that each receives some light directly from the vapour cell. The vapour cell can contain any suitable vapour offering a spectra with absorption peaks at frequencies of interest to the user, and usually contains the vapour of a metal particularly an alkali metal, with Rubidium being a common choice.

It is accordingly an object of the present invention to provide an improved Modulation Transfer Spectroscopy (MTS) device for providing a signal for stabilising the frequency of a laser. According to an aspect of the present invention there is provided a Modulation Transfer Spectroscopy (MTS) device for providing a signal for stabilising the frequency of a laser as set out in claim 1.

### BRIEF DESCRIPTION OF THE DRAWINGS

The invention will now be described, purely by way of example, with reference to the accompanying drawings, in which;

FIG. 1 is a schematic of a Modulation Transfer Spectroscopy device of the Prior Art;

FIG. 2 is a schematic of a Modulation Transfer Spectroscopy device according to one embodiment of the invention; and

FIG. 3 is a schematic of a Modulation Transfer Spectroscopy device according to another embodiment of the invention.

The drawings are for illustrative purposes only and are not to scale.

### DETAILED DESCRIPTION

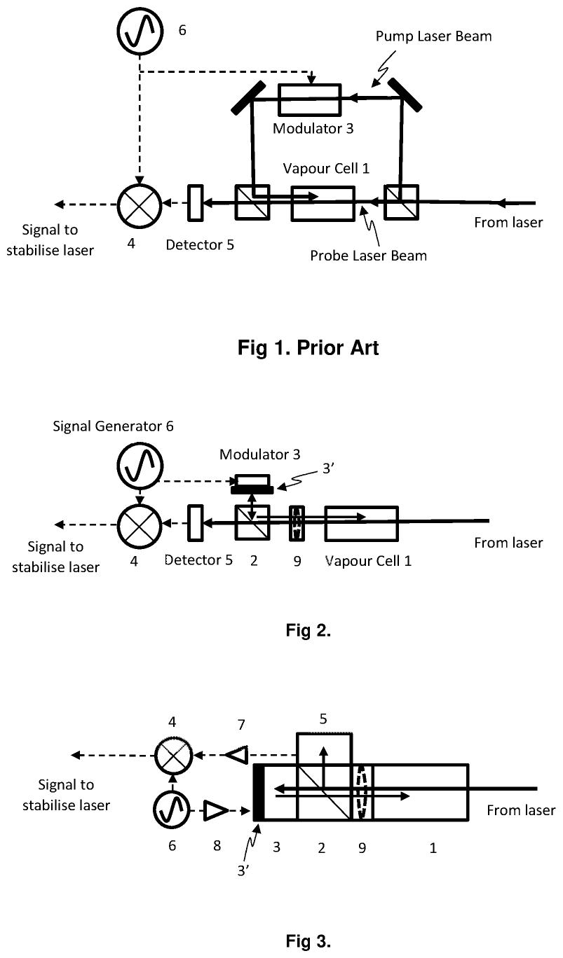

FIG. 1 is a diagram showing an optical layout of a Modulation Transfer Spectroscopy (MTS) device, of the prior art, and of the type disclosed by Sanglok et al. Here, a laser provides a laser beam in from the left (generally within a fibre optic cable) to be split by a beam splitter into two paths. The upper path goes through a modulator 3 to provide a pump laser beam that is directed into the left hand side of the vapour cell 1. The lower path provides a probe laser beam, is directed straight into the right hand side of the vapour cell. The two beams interact within a Rubidium vapour and the modulation in the pump beam gives rise to a modulation in the probe beam thanks to 4 wave mixing, and the phase of the modulation in the probe beam (relative to the phase of the modulation provided to the pump beam provided by modulator 3) depends on whether the laser frequency (which generally is one clear frequency) happens to be slightly above, or slightly below, a relevant absorption frequency of Rubidium vapour.

FIG. 2 is a diagram showing an optical layout of an MTS according to an embodiment of the present invention. As with the prior art, a laser beam is received from the right hand side into a vapour cell 1 and in doing so provides a probe laser beam. Unlike the prior art however, the pump laser beam is created from the probe laser beam exiting the vapour cell 1, by passing it to an optical modulator 3 and reflecting it back the way it came, back into the vapour cell 1. In this embodiment this is done via a beam splitter 2 and the optical modulator has the form of a piezo electric actuator actuating a mirror 3′. The mirror 3′ is shown flat but could equally be in the shape of a retroreflector, i.e. having surfaces at 90 degrees to one another. A prism 9 could be use rather than a mirror. Here, to reduce the importance of accurately orienting the mirror, an optional lens 9 may be used to focus the light onto the flat mirror which is arranged so that the optical path length to the mirror equals its focal length.

In any embodiment the beamsplitter may be a polarizing beam splitter, or may be a non-polarising beam-splitter. The former makes it easier to optimise the splitting ratio (to the detector and mirror 3′ respectively) and also reduces optical losses for the return (pump) beam. This however requires the incident beam from the laser to be correctly polarized—which may be achieved via a waveplate/retarder or rotation of the fibre collimator assuming the laser comes from a polarization maintaining fibre. By contrast the use of a non-polarizing splitter typically results in greater optical losses, but has the advantage of making the system less sensitive to unwanted influence of any polarization fluctuations in the incoming laser light.

The inventor has found however that the use of a non-polarising beam splitter offers improved performance, and preferably it is arranged or adapted to split incoming light substantially half and half (preferably between 40:60 and 60:40, more preferably between 45:55 and 55:45, with 50:50 being optimal in at least some embodiments). In the examples of 40:60 or 60:40 beam splitting, this would result in the pump beam having 40% or 60% of the strength of the probe beam (i.e., it does not result in the pump beam being stronger than the probe beam, since the pump beam will be a returned fraction of the probe beam).

FIG. 3 is a diagram showing an optical layout of an MTS according to another embodiment of the present invention. As in FIG. 2 the laser beam is introduced to the vapour cell 1 from the right hand side, and a pump beam is created from the probe beam exiting the vapour cell 1 by passing it to reflective optical modulator 3, which in this embodiment is an electro optic modulator positioned in front of a mirror 3′. Again, a prism or other retroreflector could be used instead of a flat mirror. To reach the modulator 3, the light exiting vapour chamber 1 passes through a beam splitter 2 which directs a portion of the light to detector 5 which may be a photodiode, whilst the remainder or some other portion of the light passes to the modulator 3 to return as a modulated pump beam. As with FIG. 2 an optional lens 9 (shown in dashed outline) is included. It is positioned to the right of the beam splitter 2, rather than having a lens between the beam splitter and modulator 3.

The beam splitter does not necessarily split the light 50:50 between the two paths, and whilst satisfactory results were achieved with only 30% passing to the optical modulator 3, preferably over 50% is passed to the optical modulator. This can be achieved either using an asymmetric beam splitter, or by using a polarisation dependent beam splitter, and adjusting the orientation of the polarisation of incoming light, e.g. using a waveplate or similar (not shown).

Optionally the modulator 3 is a transmission modulator (modulating the phase of light passing through it, as opposed to a reflection modulator such as a piezo-electrically actuated mirror), such as an electro-optical-modulator (EOM), which may be placed before, or adjacent to a mirror. Where a transmission modulator is used with a mirror, a quarter-waveplate (not shown) is preferably arranged between the transmission modulator and the mirror. This has been found to significantly improve the signal over any present noise (stronger signal to noise ratio), and can help prevent a standing wave being generated or sustained inside the transmission modulator (e.g. electro optical modulator) which could otherwise lead to residual and undesirable amplitude modulation. As such the transmission modulator, quarter-waveplate and mirror may be arranged adjacent and in contact (e.g. substantially laminar) and optionally bonded together.

In both FIGS. 2 and 3, a signal generator 6 is provided, issuing an electrical modulation signal which can for example be a sine wave. This is directed to the modulator 3, optionally via amplifier 8, to drive a modulation in the laser beam to generate the pump laser beam to be fed into the left hand side of vapour cell 1 (Electrical signals are depicted in the figures as dashed lines). Optical detector 5, which is typically a photodiode, outputs an electrical signal with variations in response to modulation in the probe laser beam received by the optical detector 5. Typically these variations will approximate a sine wave, which may be amplified by amplifier 7 before being fed to comparator 4. The comparator outputs a signal, typically a DC voltage, dependent on the phase difference between the two signals-the signal driving the modulator, and the signal from the detector. This signal can be used to adjust the frequency of the laser (which is not part of the MTS) such that the frequency of the laser becomes far more stable than when no MTS is used, such that the frequency stabilises at (or depending how the comparator is configured extremely close to), the frequency of a relevant absorption line in the spectra of the vapour in the vapour cell 1.

The optical modulator optionally comprises a piezo-actuated retroreflector, preferably a flat mirror 3′ (in this case he mirror forms its front surface, whereas in FIG. 2 an optical modulator is used with the mirror being positioned behind it), which has been found to offer adequate performance in a very small package. An alternative is an electro optical modulator arranged to provide a path of varying optical refractive index, and a retroreflector (behind it) which has been found to offer an excellent balance of performance and small size. In both cases the retroreflector may be a single flat mirror 3′, and further, the second optical port of the vapour cell may be provided with a focusing lens having a focal length equal to the optical path to the single flat mirror. This approach minimises the need to accurately align the mirror and provides excellent performance in a very simple and compact design.

Preferably the optical apparatus comprises an optical splitter arranged to direct the first portion of the received probe laser beam to the optical modulation detector, and the second portion via the optical modulator back into the second optical port of the vapour cell. Indeed, preferably the optical modulator is arranged adjacent to the optical splitter, and in-line with the vapour cell, and the optical detector is arranged off axis to the vapour cell. This has the advantage of providing a reliable and very compact design. Furthermore, the vapour cell, optical splitter, optical modulator, optical modulation detector may be physically bonded to each other, e.g. using glue, in order to provide a substantially monolithic optical structure which affords great resilience to physical vibration.

Optionally the MTS device has a maximum physical dimension of less than 10 cm, preferably less than 5 cm. This has the advantage of suiting portable applications and is more readily achievable than using the prior art two-pronged optical inlet design. On the same basis, MTS device optionally has a total volume of less than 14 cubic cm, preferably less than 5 cubic cm. It is suggested that the volume of the device be assessed as being the volume of the smallest notional cuboid that the components (those listed in a claim), in their assembled state, would fit within.

More generally there is provided a Modulation Transfer Spectroscopy (MTS) device comprising a vapour cell, a retroreflective optical modulation detector arranged to generate a pump laser beam from the probe laser beam emerging from the vapour cell, a modulation detector arranged to detect modulation in a probe laser beam, and a comparator arranged to provide a signal based on the phase of the modulation in the probe laser beam which can be used to stabilise the frequency of a laser. This provides for a more compact and robust MTS device.

It will be understood that the present invention has been described above purely by way of example, and modification of detail can be made within the scope of the invention.

1. A Modulation Transfer Spectroscopy (MTS) device for providing a signal for stabilising the frequency of a laser, comprising:
a vapour cell having a first optical port for receiving a probe laser beam, and a second optical port for receiving a pump laser beam, arranged to have said probe and pump laser beams superimposed within a vapour therein, to apply a frequency modulation to the probe laser beam and to output the probe laser beam through the second optical port;
an optical apparatus comprising an optical modulator and an optical modulation detector, arranged:
to apply a frequency modulation to the pump laser beam in accordance with a first electrical signal, and direct the frequency modulated pump laser beam into the second optical port of the vapour cell in order to drive the vapour cell to apply the aforementioned frequency modulation to the probe laser beam; and
to receive a first portion of the probe laser beam, from the second optical port of the vapour cell, to the optical modulation detector to detect an optical modulation therein, to generate a second electrical signal;
a signal comparator arranged to compare the first and second electrical signals, to provide a comparison electrical signal for stabilising the frequency of a laser;
wherein the optical apparatus is arranged to receive the probe laser beam outward from the second optical port of the vapour cell, and to direct a second portion thereof, via the optical modulator, and back inward through that second optical port of the vapour cell so as to provide the aforementioned frequency modulated pump laser beam.

2. The MTS device of claim 1 wherein the optical modulator comprises a piezo-actuated retroreflector.

3. The MTS device of claim 1 wherein the optical modulator comprises an electro optical modulator arranged to provide a path of varying optical refractive index, and a retroreflector.

4. The MTS device of claim 2, wherein the retroreflector is a single flat mirror.

5. The MTS device of claim 1, wherein the second optical port of the vapour cell is provided with a focusing lens having a focal length equal to the optical path to the single flat mirror.

6. The MTS device of any one of claim 1, wherein the optical apparatus comprises a partially reflective optical splitter arranged to direct the first portion of the received probe laser beam to the optical modulation detector, and the second portion via the optical modulator back into the second optical port of the vapour cell.

7. The MTS device of claim 6 wherein the optical modulator is arranged adjacent to the optical splitter, and in-line with the vapour cell, and the optical detector is arranged off axis to the vapour cell.

8. The MTS device of claim 6 wherein the vapour cell, optical splitter, optical modulator, optical modulation detector are physically bonded to each other.

9. The MTS device of claim 1 having a maximum physical dimension of less than 10 cm.

10. The MTS device of claim 9 having a maximum physical dimension of less than 5 cm.

11. The MTS device of claim 1, having a total volume of less than 14 cubic cm.

12. The MTS device of claim 11, having a total volume of less than 5 cubic cm.
